(19) United States
(12) Patent Application Publication
(10) Pub. No.: US 2005/0224794 A1
(43) Pub. Date: Oct. 13, 2005

(54) Semiconductor device manufacturing method

(75) Inventors: Naoaki Tanaka, Osaka (JP); Yuji Tsukada, Ora-gun (JP); Yuichi Watanabe, Tatebayashi-shi (JP)

Correspondence Address: Barry E. Bretschneider;Morrison & Foerster LLP, Suite 300, 1650 Tysons Boulevard, McLean, VA, 22102, US

(73) Assignee: Sanyo Electric Co., Ltd., Moriguchi-city (JP)

(21) Appl. No.: 11/087,742

(22) Filed: Mar. 24, 2005

(30) Foreign Application Priority Data
Mar. 25, 2004 (JP) 2004-089493

(51) Int. Cl. H01L 29/04

(52) U.S. Cl. 257/59

(57) ABSTRACT

The invention provides a method of forming an electrode or wiring which prevents reattachment of an etching residue in following processes by removing the etching residue at a bevel portion of a semiconductor wafer. An insulation film is formed so as to cover a front surface and a back surface of a semiconductor wafer, and then a conductive film is formed on a whole surface of the insulation film. Next, a photoresist layer is selectively formed on the conductive film by an exposure and development process. The conductive film is then selectively removed by an isotropic etching with using this photoresist layer as a mask, thereby forming an electrode or wiring of a semiconductor device. Since the electrode or the wiring of the semiconductor device is formed by isotropically etching the conductive film, a hangnail-like etching residue causing dust does not occur at the bevel portion of the wafer even though the conductive film remains on the back side of the semiconductor wafer.

### CROSS-REFERENCE OF THE INVENTION

This invention is based on Japanese Patent Application No. 2004-089493, the content of which is incorporated by reference in its entirety.

### BACKGROUND OF THE INVENTION

1. Field of the Invention

This invention relates to a semiconductor device manufacturing method, particularly to a method of forming an electrode or wiring on a semiconductor wafer with an insulation film therebetween.

2. Description of the Related Art

FIG. 5 is a cross-sectional view of a general semiconductor device. A gate electrode 52 is formed on a semiconductor wafer 50 with a gate insulation film 51 therebetween. Source and drain regions 53 and 54 are formed on a front surface of the wafer 50 in positions adjacent to the gate electrode 52. In a conventional and general semiconductor device manufacturing method, a conductive film for forming the gate electrode 52 is formed on the gate insulation film 51, and then the conductive film is anisotropically etched with using a photoresist layer selectively formed on the conductive film as a mask, thereby forming the gate electrode 52. In a similar manner to this, the conductive film is anisotropically etched to form wiring in a predetermined pattern. The relevant technology is described in Japanese Patent Application Publication No. Hei 5-41450.

By this anisotropic etching, however, the conductive film formed for forming the gate electrode, the electrode, and the wiring on the front side of the semiconductor wafer 50 is partially removed by an etching to leave the gate electrode 52, the electrode, and the wiring, while the conductive film 52a on a back side of the semiconductor wafer 50 remains as it is, as shown in FIG. 6. Particularly at a bevel portion (an end surface) 55 of the semiconductor wafer 50, a hangnail-like etching residue 52b of the conductive film 52a is left. Therefore, this etching residue 52b is peeled off in following processes, causing dust.

Such dust causes an serious problem of reducing a yield or a reliability of products at a semiconductor manufacturing site.

### SUMMARY OF THE INVENTION

The invention provides a method of manufacturing a semiconductor device. The method includes forming a conductive film on a semiconductor wafer, and forming an electrode or a wiring by etching isotropically the conductive film.

The invention also includes another method of manufacturing a semiconductor device. The method includes forming a concave portion and a convex portion on a semiconductor wafer, forming a conductive film on the concave portion and the convex portion, forming a coating film on the conductive film, etching anisotropically the coating film and the conductive film so as to remove the coating film and to reduce a thickness of the conductive film by a predetermined amount, and etching isotropically the conductive film of the reduced thickness so as to form an electrode or a wiring in the concave portion.

The invention provides yet another method of manufacturing a semiconductor device. The method includes forming a concave portion and a convex portion on a semiconductor wafer, forming a conductive film on the concave portion and the convex portion, and forming a conductive wiring or a conductive plug in the concave portion by etching isotropically the conductive film.

The invention provides another method of manufacturing a semiconductor device. The method includes forming a conductive film on a semiconductor wafer, forming an electrode or a wiring by etching anisotropically the conductive film, forming a protection film so as to cover the electrode or the wiring and to leave a bevel portion of the semiconductor wafer uncovered, and removing an etching residue at the bevel portion by etching isotropically the semiconductor wafer covered by the protection film.

### BRIEF DESCRIPTION OF THE DRAWINGS

FIGS. 1A, 1B and 1C are cross-sectional views showing a semiconductor device manufacturing method of an embodiment of the invention.

FIGS. 2A and 2B are cross-sectional views showing a semiconductor device manufacturing method of an embodiment of the invention.

FIGS. 3A and 3B are cross-sectional views showing a semiconductor device manufacturing method of an embodiment of the invention.

FIGS. 4A and 4B are cross-sectional views showing a semiconductor device manufacturing method of an embodiment of the invention.

FIG. 5 is a cross-sectional view showing a semiconductor device manufacturing method of a conventional art.

FIG. 6 is a cross-sectional view showing the semiconductor device manufacturing method of the conventional art.

### DETAILED DESCRIPTION OF THE INVENTION

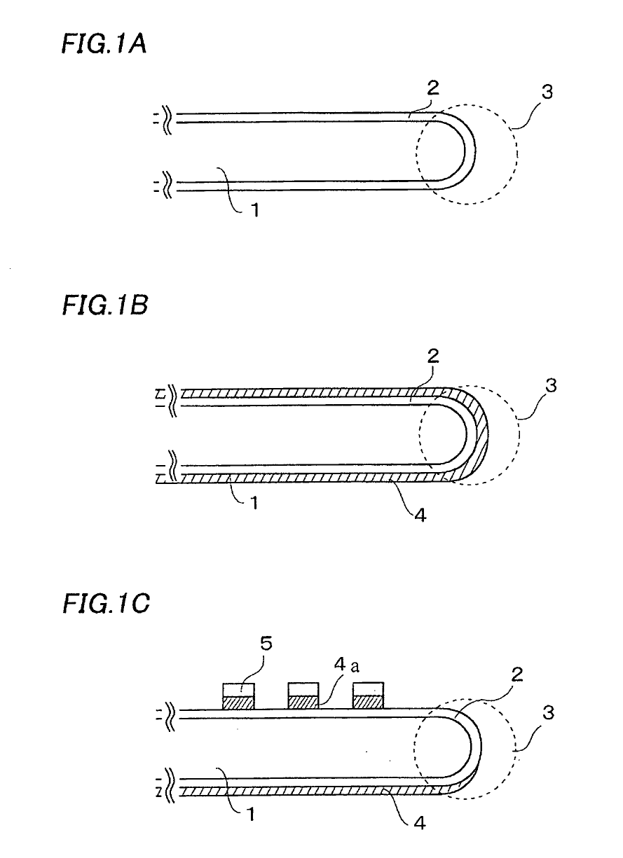

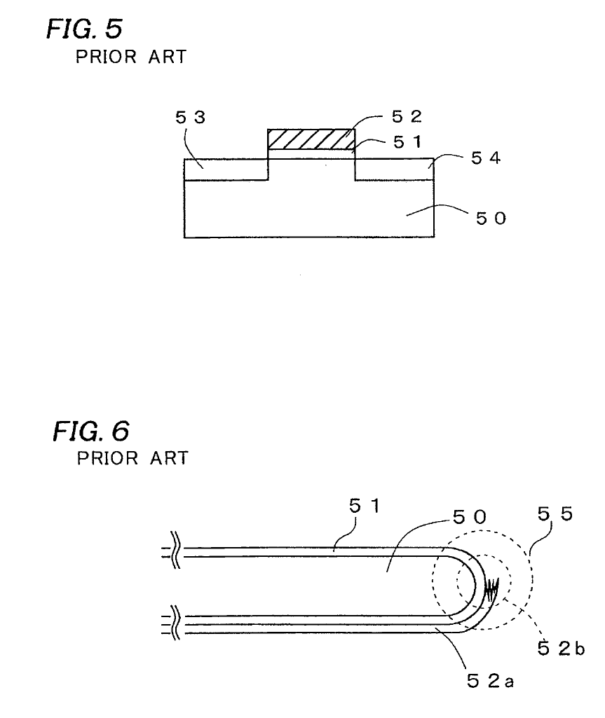

Semiconductor device manufacturing methods of the invention will be described with reference to FIGS. 1A to 4B. Description of a structure of the semiconductor device itself will be omitted since the structure is the same as the conventional one shown in FIG. 5, and a manufacturing process for preventing dust will be described in detail.

First, a semiconductor device manufacturing method of a first embodiment of the invention will be described with reference to drawings. FIGS. 1A, 1B, and 1C are cross-sectional views of a bevel portion 3 (an end surface) of a semiconductor wafer 1. As shown in FIG. 1A, a semiconductor wafer 1 is prepared, and then an insulation film 2 (e.g. a silicon oxide film by a thermal oxidation method or a CVD method) is formed so as to cover a front surface and a back surface of the semiconductor wafer 1. Next, as shown in FIG. 1B, a conductive film 4 (e.g. a polysilicon film, a tungsten silicide film, or a laminated film of these) is formed on the whole surface of the insulation film 2. Then, as shown in FIG. 1C, a photoresist layer 5 is selectively formed on the conductive film 4 by an exposure and development process. The conductive film 4 is then selectively removed by an isotropic etching with using the photoresist layer 5 as a mask to form an electrode (including a gate electrode) or wiring 4a of the semiconductor device (e.g. a MOS transistor). An isotropic etching generally means an etching in which the rate of etching reaction is the same in any direction. Although conventionally an anisotropic etching is performed in a process of forming an electrode or wiring, an isotropic etching is performed to the conductive film 4 to form the electrode or wiring 4a of the semiconductor device in this embodiment. Therefore, even though the conductive film 4 remains on the back side of the semiconductor wafer 1, a hangnail-like etching residue causing dust does not occur at a bevel portion 3 of the wafer 1, as shown in FIG. 1C. Simple gas of NF₃ or SF₆, or mixture gas including any one of NF₃ and SF₆, at least is used as etching gas in this process.

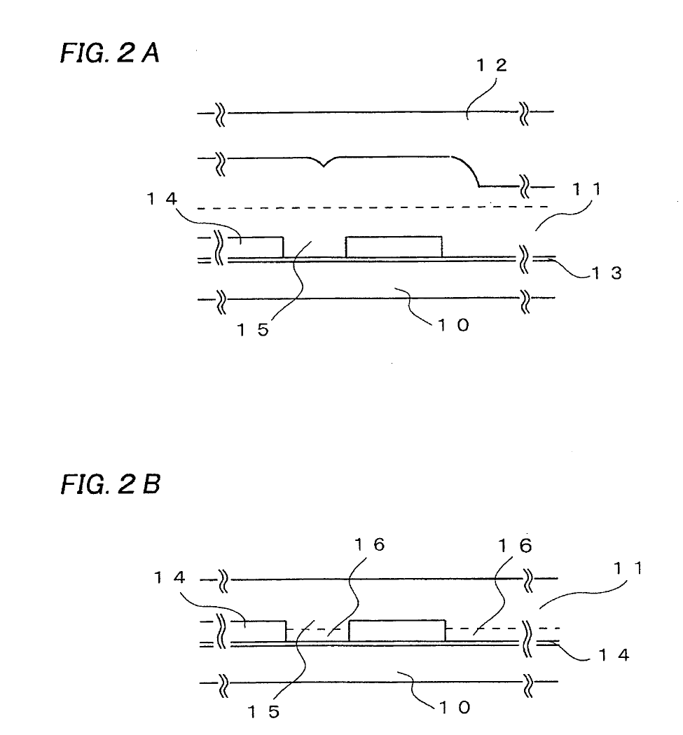

Next, a semiconductor device manufacturing method of a second embodiment of the invention will be described with reference to drawings. FIGS. 2A and 2B are cross-sectional views of a semiconductor wafer 10. First, the semiconductor wafer 10 is prepared, and then an insulation film 13 (e.g. a silicon oxide film by a thermal oxidation method or a CVD method) is formed so as to cover a front surface of the semiconductor wafer 10. Next, an insulation film such as a silicon oxide film or a silicon nitride film is further formed on this insulation film 13 by the CVD method, and a convex portion 14 is selectively formed by patterning this insulation film. It is noted that this convex portion 14 can be formed with an electrode or wiring formed of a polysilicon film and so on in the insulation film.

A concave portion 15 is formed by formation of the convex portion 14, so that concaves and convexes are formed on the insulation film 13. A reason why the concave portion 15 is formed on the insulation film 13 is to leave a conductive film 11 in the concave portion 15 to form an electrode or wiring as described below. It is noted that the insulation film 13 under the concave portion 15 is removed to form a contact hole in a case where an electrode or wiring is formed in direct contact with a diffusion region such as source/drain regions formed on the front surface of the semiconductor wafer 10.

Next, the conductive film 11 (e.g. a polysilicon film, a tungsten silicide film, or a laminated film of these) is formed on whole surfaces of the insulation film 13, the convex portion 14, and the concave portion 15. Then, a coating film 12 (e.g. a resist film, a SOG (Spin On Glass) film, a BARC (Bottom Anti-Reflection Coating) film and so on) is formed on the conductive film 11. It is noted that the material of the coating film 12 is not limited to the above materials, but it is preferable that the conductive film 11 and the coating film 12 have almost same etching rates practically for planarizing the conductive film 11 by an etching-back process.

Then, the coating film 12 and the conductive film 11 are etched back by an anisotropic etching. An anisotropic etching generally means an etching in which the etch rate in the direction normal to the surface is much higher than in direction parallel to the surface. This etching-back process by the anisotropic etching is performed to a predetermined thickness position above the convex portion 14 in the conductive film 11 as shown by a dotted line in FIG. 2A. By this process, planarization can be performed to a protruding portion of the conductive film 11 formed by reflecting the convex portion 14 and the concave portion 15. It is noted that mixture gas of Cl₂ and CF₄ at least is used as etching gas in this process.

Then, the remaining conductive film 11 planarized in the above process is isotropically etched to a predetermined position in the concave portion 15 shown by a dotted line in FIG. 2B, thereby forming an electrode or wiring 16. The predetermined position is determined in correspondence to a thickness of the electrode or wiring 16. Simple gas of NF₃ or SF₆, or mixture gas including any one of NF₃ and SF₆, at least, which is gas containing fluorine, is used as etching gas in this process. The change between the isotropic etching and the anisotropic etching can be made by changing the type of etching gas as described above and changing a parameter of an etching device. For example, the NF₃ gas makes the etching isotropic, and the isotropy increases as the voltage applied to an upper electrode (plasma source side) of the etching device increases and the voltage applied to a lower electrode thereof decreases more.

A feature of the second embodiment of the invention is to form the coating film 12 and etch back the coating film 12 and the conductive film 11 by the anisotropic etching to planarize the conductive film 11 formed on the convex portion 14 and the concave portion 15 having an uneven surface reflecting these convex portion 14 and concave portion 15. Etching back the conductive film 11 by the anisotropic etching makes a following isotropic etching performed more uniformly.

Furthermore, in this embodiment, since the electrode or wiring 16 is formed by isotropically etching the conductive film 11, a hangnail-like etching residue causing dust does not occur at a bevel portion of the semiconductor wafer 10.

Although the concave portion 15 is formed by forming the convex portion 14 on the insulation film 13 in this embodiment, the convex portion 14 and the concave portion 15 can be formed on the insulation film 13 by selectively removing the insulation film 13 by an etching, for example.

The material of the convex portion 14 is not limited to the insulation film as long as the convex portion 15 can be formed, and can have a laminated structure of an electrode, wiring or a conductive plug made of a conductive material such as a polysilicon film and an insulation film such as a silicon oxide film or a silicon nitride film covering the electrode or wiring. In this case, for example, a polysilicon film is formed on the insulation film 13 by a CVD method, and then the polysilicon film is patterned by an etching. Then, the patterned polysilicon film is covered with an insulation film such as a silicon oxide film by a thermal oxidation method or the CVD method, thereby forming the convex portion 14. It is noted that the conductive material is not limited to the polysilicon film, and can be a tungsten silicide film or a laminated film of a polysilicon film and a tungsten silicide film.

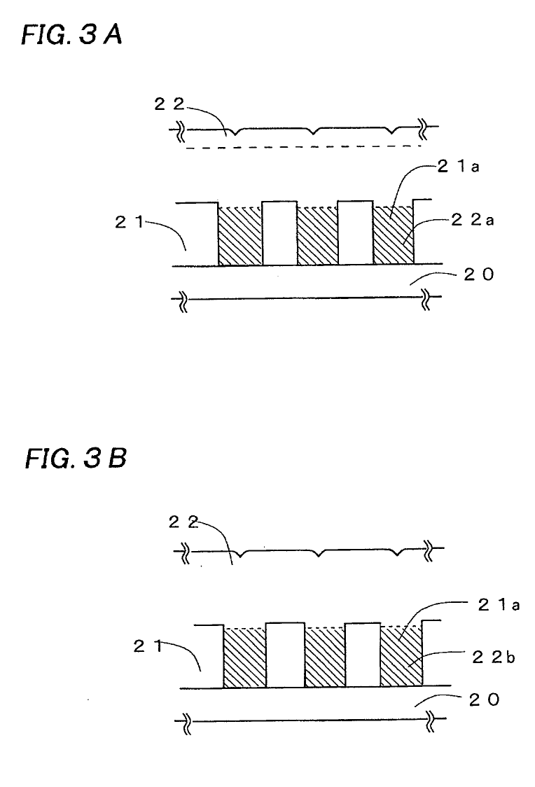

Next, a semiconductor device manufacturing method of a third embodiment of the invention will be described with reference to drawings. The third embodiment is applied to a case where a conductive film is embedded in a narrow space such as a contact hole. FIGS. 3A and 3B are cross-sectional views of a semiconductor wafer 20.

First, the semiconductor wafer 20 is prepared, and then an insulation film 21 (e.g. a silicon oxide film by a thermal oxidation method or a CVD method) is formed so as to cover a front surface of the semiconductor wafer 20 in order to form a concave portion 21a on the semiconductor wafer 20. A reason why the concave portion 21a is formed on the semiconductor wafer 20 is to leave a conductive film 22 in the concave portion 21a to form conductive wiring or a conductive plug as described below.

Next, a photoresist layer is selectively formed on the insulation film 21, and then the insulation film 21 is selectively removed by an etching with using the photoresist layer as a mask, thereby forming the concave portion 21a. The concave portion 21a functions as a contact hole extending from a front surface of the insulation film 21 to the front surface of the semiconductor wafer 20.

Then, a conductive film 22 (e.g. a polysilicon film, a tungsten silicide film, or a laminated film of these) is formed on a whole surface of the semiconductor wafer 20 including in the concave portion 21a by a CVD method. Then, in a similar manner to the second embodiment described above, the conductive film 22 is etched back to a predetermined thickness position of the conductive film 22 by an anisotropic etching, and then the remaining conductive film 22 is etched back by an isotropic etching, thereby forming a conductive plug 22a in the concave portion 21a. Alternatively, the conductive plug 22b can be formed by etching back the conductive film 22 all by an isotropic etching as shown in FIG. 3B.

The concave portion 21a functions as the contact hole extending from the front surface of the insulation film to the front surface of the semiconductor wafer 20 so that the conductive plug 22a is formed in the concave portion 21a in this embodiment, but modifications are possible. For example, the concave portion 21a is not necessarily formed extending from the front surface of the insulation film to the front surface of the semiconductor wafer 20, or conductive wiring can be formed in the concave portion 21a in a similar manner to the second embodiment.

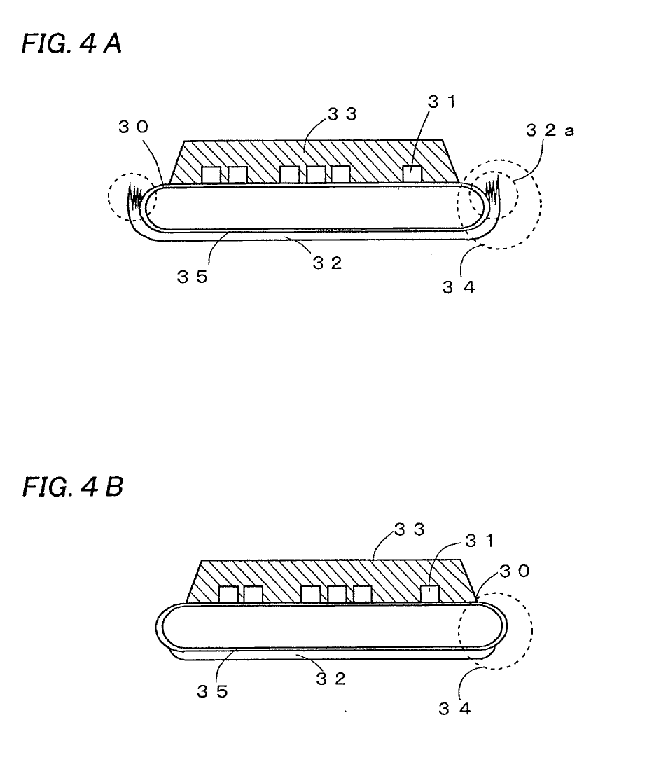

Next, a semiconductor device manufacturing method of a fourth embodiment of the invention will be described with reference to drawings. First, a semiconductor wafer 30 is prepared, and then an insulation film 35 (e.g. a silicon oxide film by a thermal oxidation method or a CVD method) is formed so as to cover a front surface and a back surface of the semiconductor wafer 30. Then, a conductive film 32 formed of, for example, a polysilicon film, a tungsten silicide film, or a laminated film of these is formed on the whole surface of the insulation film 35. Then, the conductive film 32 is anisotropically etched to form an electrode or wiring 31. At this time, since the anisotropic etching is performed to the conductive film 32, an etching residue 32a of the conductive film 32 remains at a bevel portion 34 of the semiconductor wafer 30 as shown in FIG. 4A.

Next, for protecting the semiconductor wafer from an outside influence, a protection film 33 formed of an oxide film or a silicon nitride film is formed so as to cover a region except the bevel portion 34 of the semiconductor wafer 30.

Then, a whole surface of the semiconductor wafer 30 is isotropically etched by a dry-etching or a wet-etching with using the protection film 33 as a mask to remove the etching residue 32a at the bevel portion 34 of the semiconductor wafer 30, as shown in FIG. 4B.

As described above, the etching residue 32a of the conductive film 32 does not remain at the bevel portion of the semiconductor wafer, or the etching residue 32a can be removed even though it remains. This can prevent reduction of a yield or a reliability of products caused by reattachment of the etching residue in following processes, as has been a problem.

1. A method of manufacturing a semiconductor device, comprising:
forming a conductive film on a semiconductor wafer; and
forming an electrode or a wiring by etching isotropically the conductive film.

2. A method of manufacturing a semiconductor device, comprising:
forming a concave portion and a convex portion on a semiconductor wafer;
forming a conductive film on the concave portion and the convex portion;
forming a coating film on the conductive film;
etching anisotropically the coating film and the conductive film so as to remove the coating film and to reduce a thickness of the conductive film by a predetermined amount; and
etching isotropically the conductive film of the reduced thickness so as to form an electrode or a wiring in the concave portion.

3. The method of claim 2, wherein the convex portion is formed of an insulation film.

4. The method of claim 2, wherein the convex portion is formed of an insulation film comprising another electrode or wiring.

5. The method of claim 2, wherein the conductive film and the coating film have substantially a same etching rate.

6. A method of manufacturing a semiconductor device, comprising:
forming a concave portion and a convex portion on a semiconductor wafer;
forming a conductive film on the concave portion and the convex portion; and
forming a conductive wiring or a conductive plug in the concave portion by etching isotropically the conductive film.

7. The method of claim 6, further comprising forming a coating film on the conductive film and etching anisotropically the coating film and the conductive film so as to remove the coating film and to reduce a thickness of the conductive film by a predetermined amount before forming the conductive wiring or the conductive plug.

8. The method of claim 6, wherein the convex portion is formed of an insulation film.

9. The method of claim 6, wherein the convex portion is formed of an insulation film comprising another conductive wiring or conductive plug or an electrode.

10. The method of claim 7, wherein the conductive film and the coating film have substantially a same etching rate.

11. A method of manufacturing a semiconductor device, comprising:
forming a conductive film on a semiconductor wafer;
forming an electrode or a wiring by etching anisotropically the conductive film;
forming a protection film so as to cover the electrode or the wiring and to leave a bevel portion of the semiconductor wafer uncovered; and
removing an etching residue at the bevel portion by etching isotropically the semiconductor wafer covered by the protection film.
